(19) United States
(12) Patent Application Publication
(10) Pub. No.: US 2025/0214109 A1
(43) Pub. Date: Jul. 3, 2025

(54) PIEZOELECTRIC DEVICE, PIEZOELECTRIC ACTUATOR, AND ULTRASONIC DEVICE

(71) Applicant: SEIKO EPSON CORPORATION, Tokyo (JP)

(72) Inventor: Chikara KOJIMA, MATSUMOTO-SHI (JP)

(21) Appl. No.: 19/002,242

(22) Filed: Dec. 26, 2024

(30) Foreign Application Priority Data
Dec. 27, 2023 (JP) 2023-220811

(51) Int. Cl. B06B 1/06

(52) U.S. Cl. CPC B06B 1/0603

(57) ABSTRACT

A piezoelectric device includes a substrate that includes an opening; a diaphragm that includes a first surface and a second surface opposite to the first surface, and that is configured such that the first surface is bonded to the substrate to close the opening; and a piezoelectric element provided on the second surface of the diaphragm, wherein the diaphragm includes a first region overlapping with the piezoelectric element and a second region not overlapping with the piezoelectric element when viewed from a thickness direction of the diaphragm, a thickness of the second region is thinner than a thickness of the first region, the second region is provided with a reinforcement material having a fracture toughness higher than that of the first region of the diaphragm, and the thickness of the second region in the thickness direction is constant, and a thickness of the reinforcement material is constant.

The present application is based on, and claims priority from JP Application Serial Number 2023-220811, filed Dec. 27, 2023, the disclosure of which is hereby incorporated by reference herein in its entirety.

### BACKGROUND

### 1. Technical Field

The present disclosure relates to a piezoelectric device, a piezoelectric actuator including the piezoelectric device, and an ultrasonic device including the piezoelectric device.

### 2. Related Art

In the related art, a piezoelectric device in which a first electrode, a piezoelectric element, and a second electrode are layered on a substrate is known. In the piezoelectric device described in JP-A-2017-126628, a piezoelectric body covers a first electrode on a diaphragm (support body), and a recess that is recessed on a diaphragm side is provided outside a region overlapping with the first electrode of the diaphragm. The piezoelectric body is provided so as to cover the first electrode. The second electrode is provided from the piezoelectric body to the diaphragm including the recess. With such a configuration, the displacement characteristic of the diaphragm can be improved by the recess.

However, when the diaphragm is made thinner to increase the displacement amount as in the case of JP-A-2017-126628, the diaphragm cannot withstand the deformation of the diaphragm and may be damaged. For this reason, there is a limit to the displacement amount of the diaphragm that can be driven by a piezoelectric element, and there is a demand for a highly durable piezoelectric device that is less likely to be damaged even when the displacement amount of the diaphragm increases.

### SUMMARY

A piezoelectric device according to a first aspect of the present disclosure includes a substrate that includes an opening; a diaphragm that includes a first surface and a second surface opposite to the first surface, and that is configured such that the first surface is bonded to the substrate to close the opening; and a piezoelectric element provided on the second surface of the diaphragm, wherein the diaphragm includes a first region overlapping with the piezoelectric element and a second region not overlapping with the piezoelectric element when viewed from a thickness direction of the diaphragm, a thickness of the second region in the thickness direction of the diaphragm is thinner than a thickness of the first region, the second region is provided with a reinforcement material made of a material having a fracture toughness higher than that of the first region of the diaphragm, and the thickness of the second region in the thickness direction is constant, and a thickness of the reinforcement material is constant.

### BRIEF DESCRIPTION OF THE DRAWINGS

FIG. 1 is a diagram showing a schematic configuration of an ultrasonic device according to a first embodiment.

FIG. 2 is a plan view showing a schematic configuration of a piezoelectric device of the first embodiment.

FIG. 3 is a schematic cross-sectional view of a case of cutting the piezoelectric device at line A-A of FIG. 2.

FIG. 4 is a schematic cross-sectional view of a case of cutting the piezoelectric device at line B-B of FIG. 2.

FIG. 5 is a table showing the approximate Young's modulus and the fracture toughness of each material.

FIG. 6 is a diagram showing a distribution of strain in an X direction applied to the vibration body 35 when the piezoelectric device of the first embodiment is driven with a driving voltage of 10 V.

FIG. 7 is a diagram showing a distribution of strain in the X direction applied to the vibration body 35 when the piezoelectric device of the first embodiment is driven with a driving voltage of 100 V.

FIG. 8 is a diagram showing the strain in the X direction at each position in the X direction of a −Z side surface of a vibration body when the piezoelectric device of the first embodiment is driven with drive voltages of 10 V and 100 V.

FIG. 9 is a diagram showing the strain in the X direction at each position in the X direction of a +Z side surface of the vibration body when the piezoelectric device of the first embodiment is driven with driving voltages of 10 V and 100 V.

FIG. 10 is a diagram showing the strain in the X direction at each position in a thickness direction of the vibration body in the piezoelectric device of the first embodiment.

FIG. 11 is a diagram showing the displacement amount of a vibration section when the driving voltage is changed in the conventional example and the present embodiment.

FIG. 12 is a diagram showing the displacement amount of the vibration section when the frequency of the ultrasonic wave output from the piezoelectric device is changed.

FIG. 13 is a plan view showing a schematic configuration of a piezoelectric device of a second embodiment.

FIG. 14 is a schematic cross-sectional view of a case of cutting the piezoelectric device at line C-C of FIG. 13.

FIG. 15 is a schematic cross-sectional view of a case of cutting the piezoelectric device at line D-D of FIG. 13.

FIG. 16 is a diagram showing a schematic configuration of a liquid ejection device as a piezoelectric actuator of a third embodiment.

### DESCRIPTION OF EMBODIMENTS

### First Embodiment

Hereinafter, an ultrasonic device including a piezoelectric device of a first embodiment of the present disclosure will be described.

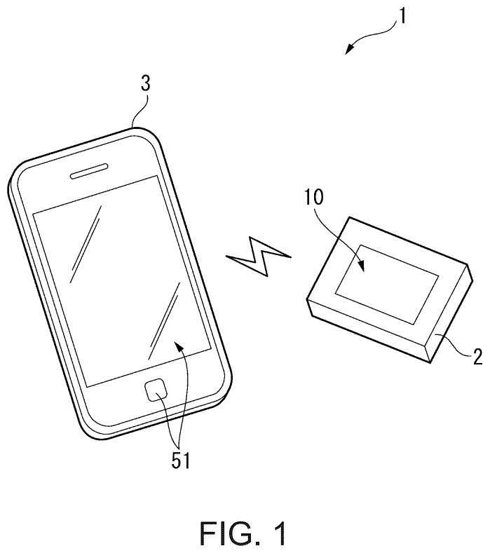

FIG. 1 is a diagram showing a schematic configuration of an ultrasonic device 1 according to the present embodiment.

The ultrasonic device 1 of the present embodiment includes a piezoelectric device 10 that functions as an ultrasonic sensor, a housing 2 that houses the piezoelectric device 10, and a measurement device 3. Although not shown, the housing 2 may also house various control circuits that control the piezoelectric device 10, a battery, a communication section that outputs measurement results to the outside, and the like.

The ultrasonic device 1 performs ultrasonic wave measurement in which an ultrasonic wave is transmitted from the piezoelectric device 10 to a measurement target and the ultrasonic wave reflected by the measurement target is received. The measurement result of the ultrasonic wave measurement output from the ultrasonic device 1 is transmitted to the measurement device 3. The measurement device 3 is, for example, a computer constituted by a dedicated computer, a smartphone, a tablet device, or the like. The measurement device 3 performs various kinds of arithmetic processing based on a measurement result of the ultrasonic wave measurement, and performs various kinds of processing such as generation of an internal tomographic image of a living body, observation of the state of a predetermined tissue in a living body, and thickness measurement.

Hereinafter, the piezoelectric device 10 used in such an ultrasonic device 1 will be described.

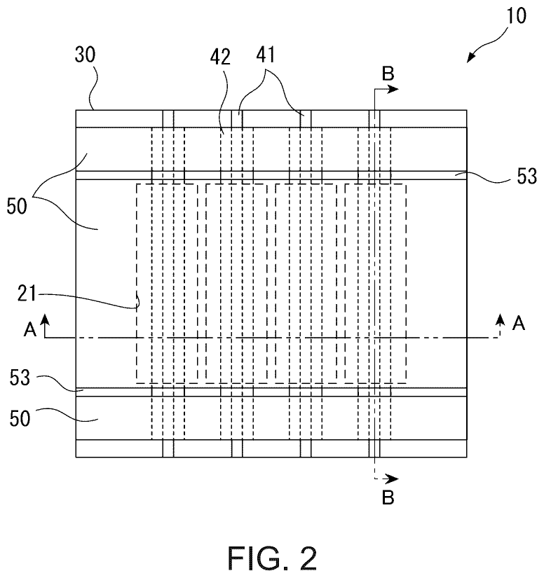

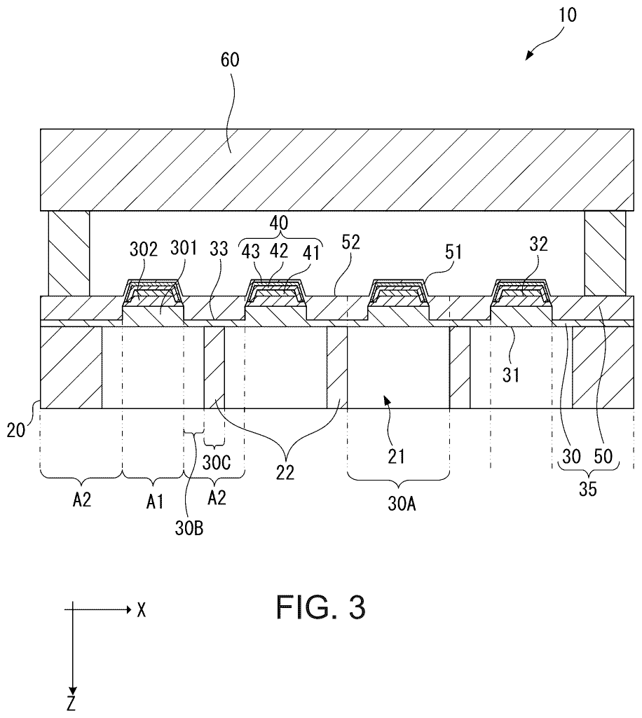

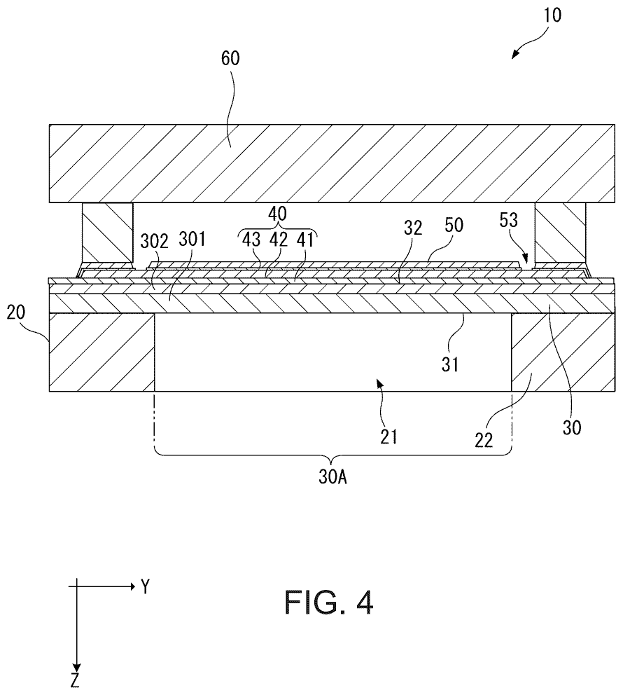

FIG. 2 is a plan view showing a schematic configuration of the piezoelectric device 10. FIGS. 3 and 4 are cross-sectional views showing a schematic configuration of the piezoelectric device 10 of the present embodiment. FIG. 3 shows a cross section of a case of cutting the piezoelectric device 10 at line A-A of FIG. 2, and FIG. 4 shows a cross section of a case of cutting the piezoelectric device 10 at line B-B of FIG. 2.

As shown in FIGS. 3 and 4, the piezoelectric device 10 of the present embodiment includes a substrate 20, a diaphragm 30 layered on the substrate 20, piezoelectric elements 40 layered on the diaphragm 30, reinforcement materials 50 provided at a predetermined portion of the diaphragm 30, and a sealing plate 60. In the present embodiment, a substrate thickness direction of the substrate 20 is defined as a Z direction, a direction orthogonal to the Z direction is defined as an X direction, and a direction orthogonal to the Z direction and the X direction is defined as a Y direction.

The substrate 20 is a plate-shaped member having a predetermined thickness, and includes openings 21 penetrating in a thickness direction. When the diaphragm 30 is layered on the substrate 20, the openings 21 are closed by the diaphragm 30.

As shown in FIGS. 2 to 4, the openings 21 are formed elongated in the Y direction, and a plurality of openings 21 are provided along the X direction. In the substrate 20, a partition 22 surrounding the opening 21 defines a vibration section 30A that is a layered body of the diaphragm 30 and the reinforcement material 50 and that is vibrated by driving the piezoelectric element 40.

In the present disclosure, the diaphragm 30 and the reinforcement material 50 constitute a vibration body 35. The vibration section 30A refers to a portion surrounded by the partition 22 in the vibration body 35. That is, in the diaphragm 30 and the reinforcement material 50, a portion overlapping with the partition 22 in the Z direction serves as a base 30C in which vibration is suppressed, and a portion surrounded by the partition 22 serves as the vibration section 30A that is vibrated by the driving of the piezoelectric element 40. The base 30C refers to a portion of the vibration body 35 that overlaps the partition 22 in the Z direction.

The diaphragm 30 includes a first surface 31 (a surface on a +Z side) facing the substrate 20 and a second surface 32 (a surface on a −Z side) on the opposite side from the first surface 31, and closes the openings 21 by the first surface 31 being bonded to cover a −Z side surface of the substrate 20.

The diaphragm 30 is, for example, a layered body including a first layer 301 formed of SiO₂ and a second layer 302 formed of ZrO₂, and is formed by processing an element substrate in which the first layer 301 is arranged on a +Z side and the second layer 302 is arranged on a −Z side. Specifically, in a case where a portion of the diaphragm 30 on which the piezoelectric element 40 is layered is defined as a first region A1 and a portion other than the first region A1 is defined as a second region A2, a recess 33 is formed in at least a portion of the second region A2 by processing such as etching from a second surface 32 side. That is, the first region A1 of the diaphragm 30 is constituted by the first layer 301 and the second layer 302, and the second region A2 of the diaphragm 30 is thinner along the Z direction than the first region A1, does not include the second layer 302 of ZrO₂, and is constituted only by the first layer 301 constituted by SiO₂. The groove depth of the recess 33 along the Z direction is equal to or greater than the half value of the thickness of the first region A1, that is, the thickness of the second region A2 is less than the half value of the thickness of the first region A1 and is uniform.

In the example shown in FIG. 3, a part of the second layer 302 is removed in the first region A1. This is a recess state section generated by over-etching when the piezoelectric element 40 is formed on the diaphragm 30 in the first region A1, and the depth in the Z direction is sufficiently small compared to the recess 33.

In the plan view viewed from the Z direction, the piezoelectric element 40 is layered in the first region A1. The second region A2 is provided at a position sandwiching at least the first region A1 in the X direction.

In the vibration body 35, the second region A2 includes a base 30C overlapping with the partition 22 of the substrate 20 and an arm 30B between the base 30C and the first region A1. The recess 33 is provided spanning at least from the arm 30B to the base 30C, and the reinforcement material 50 that constitutes the vibration body 35 together with the diaphragm 30 is provided in the recess 33.

The piezoelectric element 40 is provided on the second surface 32 of the diaphragm 30 at a position overlapping with the first region A1 of the diaphragm 30. The piezoelectric element 40 is formed of, for example, a layered body in which a first electrode 41, a piezoelectric film 42, and a second electrode 43 are layered from the diaphragm 30 toward a-Z side.

The piezoelectric elements 40 are formed as follows. First, an electrode film is formed on the diaphragm 30, and then the first electrodes 41 are patterned by etching. Next, after piezoelectric films 42 which cover the first electrodes 41 are formed, the piezoelectric films 42 are patterned by etching. Further, after electrode films covering the piezoelectric films 42 and the first electrodes 41 are formed, the second electrodes 43 are patterned by etching. By this, as shown in FIGS. 3 and 4, a side surface of the piezoelectric element 40 is a tapered surface inclined with respect to the Z direction.

In the present embodiment, a single ultrasonic transducer is constituted by the vibration section 30A and the piezoelectric element 40.

In such an ultrasonic transducer, when a square wave voltage (drive signal) of a predetermined frequency is applied between the first electrode 41 and the second electrode 43, the piezoelectric film 42 expands and contracts, and the vibration section 30A vibrates due to the expansion and contraction of the piezoelectric film 42, thereby transmitting ultrasonic waves to a +Z side. When the vibration section 30A is vibrated by ultrasonic waves, the piezoelectric film 42 bends, and a potential difference is generated between a first electrode 41 side and a second electrode 43 side of the piezoelectric film 42. By this, it is possible to detect the reception of ultrasonic waves by detecting a potential difference generated between the first electrode 41 and the second electrode 43.

The reinforcement material 50 is arranged with a uniform thickness in the recess 33 provided in the second region A2 of the diaphragm 30. The thickness of the reinforcement material 50 at the position of the recess 33 is at least equal to or greater than half the thickness at the first region A1. It is desirable that a third surface 52, which is a −Z side surface of the reinforcement material 50, is located on the same surface as the second surface 32 of the diaphragm 30 in the first region A1 or on a −Z side of the second surface 32.

A part of the reinforcement material 50 is formed across the second region A2 and the first region A1. That is, the reinforcement material 50 is formed on the diaphragm 30 on which the piezoelectric element 40 is formed by a method such as sputtering. Therefore, as shown in FIG. 3, a part of the reinforcement material 50 extends from the second region A2 along the tapered surface of the second electrode 43, and constitutes an extension section 51. As shown in FIGS. 2 to 4, the reinforcement material 50 may be provided to cover the piezoelectric element 40. In this case, as shown in FIGS. 1 and 3, the reinforcement material 50 is removed (for example, etched) until surfaces of the piezoelectric film 42 and the diaphragm 30 are exposed on a +Y side of the piezoelectric element 40 sandwiching the vibration section 30A to form a insulation groove 53. By this, it is possible to avoid that the first electrode 41 and the second electrode 43 are electrically connected to each other by the conductive reinforcement material 50.

Further, in a case where each of the piezoelectric elements 40 arranged in the X direction is driven individually, the reinforcement materials 50 at +Y side end sections of the diaphragm 30 are removed so that the first electrodes 41 of each of the piezoelectric elements 40 are not conductive. By this, an end section of the first electrode 41 of each piezoelectric element 40 is exposed on the diaphragm 30.

The reinforcement material 50 is made of a material having a higher fracture toughness than that of the diaphragm 30. More desirably, the reinforcement material 50 is made of a material having a Young's modulus smaller than that of the material having the highest Young's modulus constituting the diaphragm 30. In the present embodiment, the diaphragm 30 is a layered body of the first layer 301 of SiO₂ and the second layer 302 of ZrO₂. When the Young's modulus of SiO₂ is 70 GPa and the Young's modulus of a ZrO₂ layer is 200 GPa, then for the material of the reinforcement material 50, it is desirable to use a material having a Young's modulus lower than at least the Young's modulus of a ZrO₂ layer.

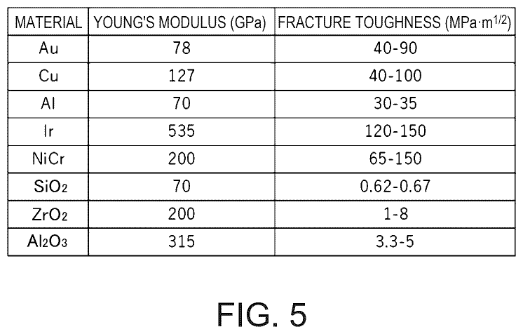

FIG. 5 is a table showing the approximate Young's modulus and the fracture toughness of each material. As can be seen from FIG. 5, when the first region A1 is a layered body of a SiO₂ layer and a ZrO₂ layer, any of Au, Cu, Al, Ir, and NiCr having higher fracture toughness is used as the reinforcement material 50. Among these, Au, Cu, and Al, which each have a Young's modulus smaller than that of a ZrO₂ layer, are desirably used. Since Cu has a larger Young's modulus than Au and Al, it is hard to bend, and Al has a smaller fracture toughness than Au and Cu. Therefore, it is most desirable to use Au as the reinforcement material 50.

The sealing plate 60 is provided on a side of the diaphragm 30 opposite from the substrate 20, and is bonded to the diaphragm 30 or the reinforcement material 50 via, for example, a resist resin or the like. A gap having a predetermined dimension is provided between the sealing plate 60 and the diaphragm 30 and the reinforcement material 50. By this, the sealing plate 60 does not come into contact with the piezoelectric element 40 or the like due to the vibration of the vibration section 30A. The sealing plate 60 is, for example, a plate-shaped member having a thickness dimension larger than those of the diaphragm 30 and the substrate 20, and reinforces the substrate 20 and the diaphragm 30 by being bonded to the diaphragm 30.

### Displacement Characteristics of Piezoelectric Device 10

Next, the displacement characteristics of the piezoelectric device 10 of the present embodiment as described above will be described.

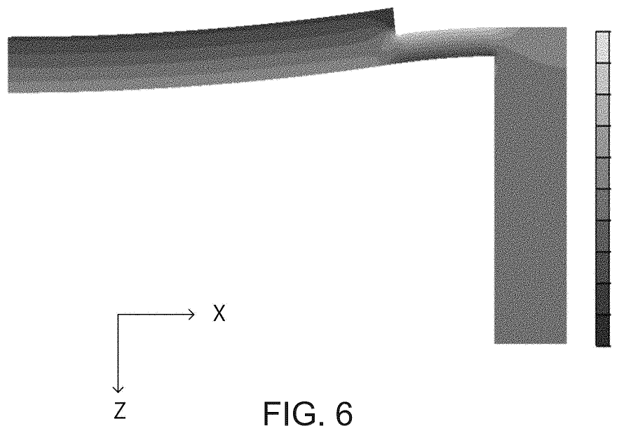

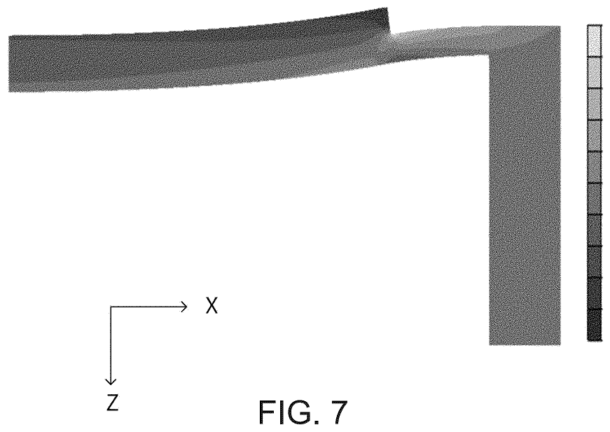

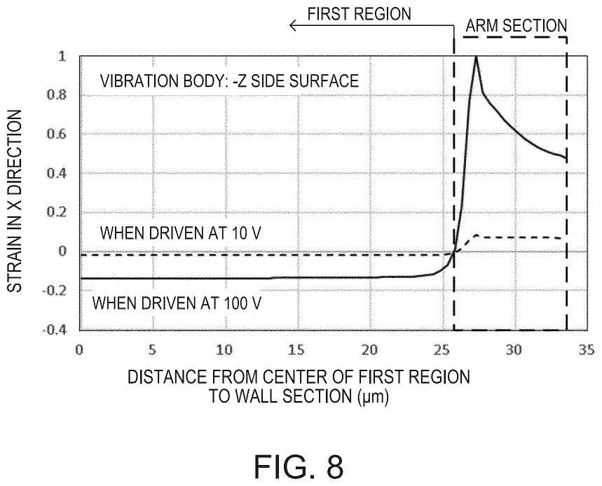

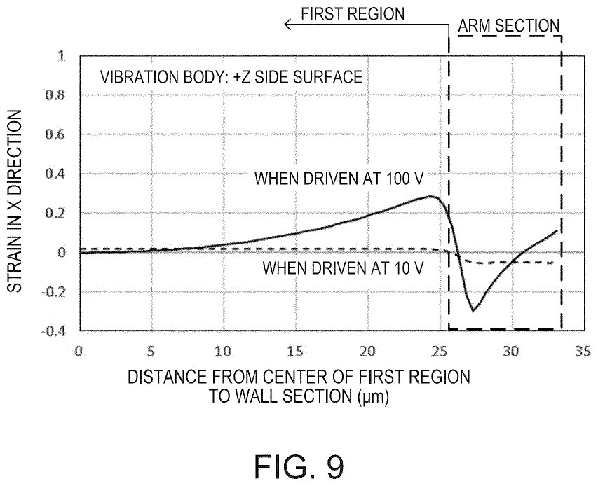

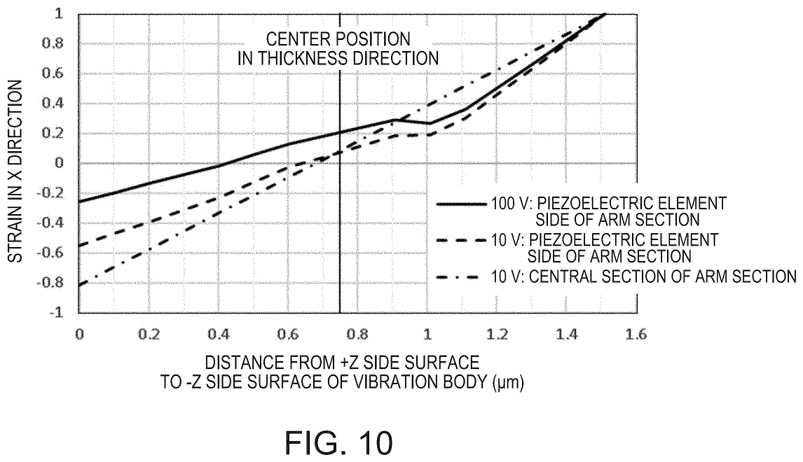

FIG. 6 is a diagram showing a distribution of strain in the X direction applied to the vibration body 35 when the piezoelectric device 10 of the present embodiment is driven with a driving voltage of 10 V. FIG. 7 is a diagram showing a distribution of strain in the X direction applied to the vibration body 35 when the piezoelectric device 10 of the present embodiment is driven by a driving voltage of 100 V. FIG. 8 is a diagram showing the strain in the X direction at each position in the X direction of a −Z side surface of the vibration body 35 when the piezoelectric device 10 of the present embodiment is driven with drive voltages of 10 V and 100 V. FIG. 9 is a diagram showing the strain in the X direction at each position in the X direction of a +Z side surface of the vibration body 35 when the piezoelectric device 10 of the present embodiment is driven with drive voltages of 10 V and 100 V. FIG. 10 is a diagram showing the strain in the X direction at each position in the thickness direction of the vibration body 35. FIG. 10 shows, as an example, results of strain measurement at a central position of the arm 30B (an intermediate position between the first region A1 and the base 30C) when the driving voltage is 10 V, at a vicinity position of the arm 30B in the first region A1 when the driving voltage is 10 V, and at a vicinity position of the arm 30B in the first region A1 when the driving voltage is 100 V.

As shown in FIGS. 6 and 7, when the driving voltage input to the piezoelectric device 10 is set to 100 V, the strain in the X direction is larger than that when the driving voltage is set to 10 V, and the strain is also larger particularly in the first region A1 of the diaphragm 30.

By the way, in a case where this type of strain in the X direction is balanced between a +Z side (a first surface 31 side) of the vibration body 35 and a −Z side (a second surface 32 side of the diaphragm 30 and a third surface 52 side of the reinforcement material 50), the strain in the X direction is cancelled by absorbing each other's strain, and thus the influence on damage or the like of the diaphragm 30 due to the strain is small.

When the driving voltage is 10 V, as shown in FIGS. 6, 8, and 9, the strain at positions of the arm 30B of the diaphragm 30 is larger than the strain in the first region A1, but the difference in strain is relatively small. In this case, as shown in FIG. 10, the strain becomes “zero” in the vicinity of the central point in the thickness direction (Z direction) of the diaphragm 30. The position where the strain is “zero” is a neutral point where the strain on a +Z side and the strain on a −Z side of the vibration body 35 cancel each other out. When the driving voltage is 10 V, the neutral point is in the vicinity of a central point position in the thickness direction (Z direction) of the diaphragm 30.

On the other hand, when the driving voltage of the diaphragm 30 is further increased, as shown in FIGS. 7 to 9, the strain in the X direction increases not only in the arm 30B but also in the first region A1, the strain increases in the first region A1 particularly on a +Z side surface of the vibration body 35, and a strain direction (compression or extension) is reversed near the boundary between the first region A1 and the second region A2 (arm 30B). At a −Z side surface of the vibration body 35, although the strain in the first region A1 is small, the strain in the arm 30B becomes remarkably large. When such strain is generated, as shown in FIG. 10, the balance of strain between a +Z side and a −Z side of the vibration body 35 is lost, and the neutral point is shifted to a first surface 31 side (+Z side).

As described above, the strain when the diaphragm 30 is displaced is not only a problem on the surface of the diaphragm 30, but also changes at each position in the thickness direction (Z direction) of the diaphragm 30. In particular, when the driving voltage is increased, since the neutral point moves to a first surface 31 side, the strain increases in a portion closer to a second surface 32 side than the neutral point.

On the other hand, in the present embodiment, the diaphragm 30 is provided with the recess 33 having a depth equal to or greater than half the thickness of the diaphragm 30 spanning from the arm 30B to the base 30C, which is outside the outer edge of the first region A1, the reinforcement material 50 is layered in the recess 33, and the third surface 52 of the reinforcement material 50 is flush with the second surface 32 of the first region A1 of the diaphragm 30. As described above, the reinforcement material 50 is made of a material having a fracture toughness larger than that of the first region A1 of the diaphragm 30. It is desirable that the depth of the recess 33 and the thickness of the reinforcement material 50 are appropriately set according to the maximum driving electric power input to the piezoelectric device 10 so that the neutral point is positioned in the reinforcement material 50.

By this, for example, when inputting a larger driving voltage such as 100 V to the piezoelectric device 10, the larger strain in the X direction that is further toward the second surface 32 (third surface 52) side than the neutral point will be in the reinforcement material 50, and it is possible to suppress damage due to the strain.

In addition, the reinforcement material 50 has a smaller Young's modulus than the second layer 302 constituting the first region A1 of the diaphragm 30. By this, the diaphragm 30 is easily displaced when the driving voltage is input, and the vibration displacement amount of the diaphragm 30 can be increased.

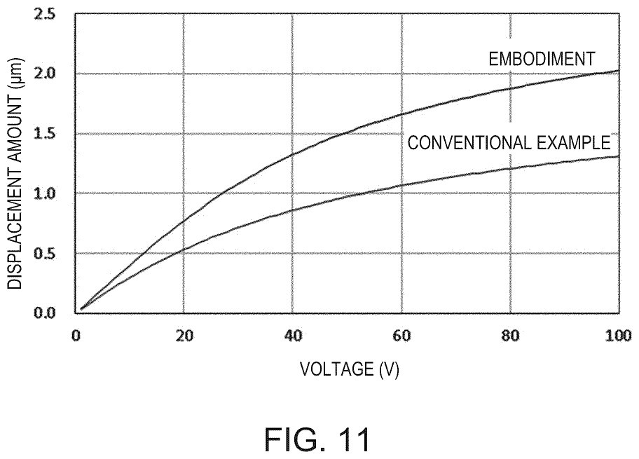

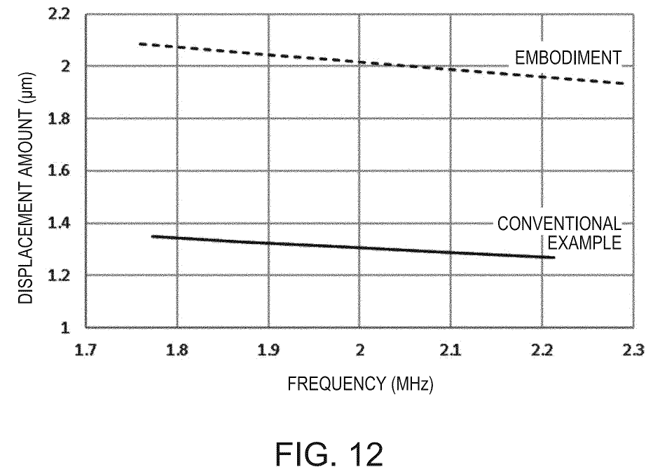

FIG. 11 is a diagram showing the displacement amount of the vibration section 30A when the driving voltage is changed in the conventional example and the present embodiment, and FIG. 12 is a diagram showing the displacement amount of the vibration section 30A when the frequency of the ultrasonic wave output from the piezoelectric device 10 is changed.

Note that in the conventional example, a piezoelectric device was used that used a diaphragm 30 having the same structure overall as the first region A1 (a layered body of SiO₂ and ZrO₂), without providing the recess 33 nor the reinforcement material 50 of the diaphragm 30 of the present embodiment.

In the piezoelectric device of the conventional example, the entire diaphragm is formed of a layered body of SiO₂ and ZrO₂. In this case, ZrO₂, which has a large Young's modulus, is provided in a portion corresponding to the arm 30B which contribute to the displacement, and the displacement amount cannot be sufficiently increased. On the other hand, in the present embodiment, there is no ZrO₂ because of the recess 33 in the arm 30B, and instead, the reinforcement material 50 having a small Young's modulus is used. Therefore, as shown in FIG. 11, in the piezoelectric device 10 of the present embodiment, with respect to the input driving voltage, it is possible to displace the vibration section 30A with a larger displacement amount than the piezoelectric device of the conventional example. As described above, even when the driving voltage is increased, the damage of the diaphragm 30 can be suppressed.

In the piezoelectric device 10, the frequency of the ultrasonic wave output from the piezoelectric device 10 can be varied by changing the frequency of the input driving voltage. As shown in FIG. 12, even when the frequency of the ultrasonic wave is changed, the piezoelectric device 10 of the present embodiment can increase the displacement amount of the diaphragm 30 more than the piezoelectric device of the comparative example.

By matching the natural frequency of the piezoelectric device 10 with the frequency of the driving voltage, the displacement amount can be further increased by the resonance effect of the diaphragm 30.

### Operations and Effects of the Present Embodiment

The piezoelectric device 10 of the present embodiment includes the substrate 20 that includes the opening 21, the diaphragm 30 that includes the first surface 31 and the second surface 32 and that is configured such that the first surface 31 is bonded to the substrate 20 to close the opening 21, and the piezoelectric element 40 provided on the second surface 32 of the diaphragm 30. The diaphragm 30 includes the first region A1 overlapping with the piezoelectric element 40 and the second region A2 not overlapping the piezoelectric element 40 when viewed from the Z direction, and the thickness of the second region A2 is thinner than the thickness of the first region A1 in the Z direction. In the second region A2, the reinforcement material 50 made of a material having a fracture toughness higher than that of the first region A1 of the diaphragm 30 is provided. The thickness of the second region A2 in the Z direction of the diaphragm 30 is constant, and the thicknesses of the reinforcement material 50 is also constant.

By this, in the piezoelectric device 10 of the present embodiment, since the reinforcement material 50 having a high fracture toughness is arranged in the second region A2, which is displaced more than the first region A1, it is possible to suppress damage of the vibration body 35 in the second region A2.

In the present embodiment, the diaphragm 30 includes the recess 33, which is recessed from a second surface 32 side in the second region A2. The groove depth of the recess 33 is equal to or greater than a half value of the thickness of the first region A1, and the reinforcement material 50 is arranged in the recess 33.

In the piezoelectric device 10 as in the present embodiment, when the driving voltage input to the piezoelectric element 40 is increased, the strain of the vibration body 35 in the X direction becomes different in magnitude in the Z direction, and the neutral point does not become the center of the vibration body 35 in the Z direction but shifts to a first surface 31 side. Therefore, the strain in the X direction on a second surface 32 side of the vibration body 35 is larger than that at the neutral point. In contrast, in the present embodiment, the thickness of the reinforcement material 50 is equal to or greater than half of the thickness at the first region A1. That is, in the Z direction, in the second region A2 of the vibration body 35, the reinforcement material 50 having high fracture toughness occupies a half or more of the thickness. Thus, damage in the second region A2 can be more effectively suppressed.

In the present embodiment, the reinforcement material 50 extends to a position straddling the boundary between the first region A1 and the second region A2 when viewed from the Z direction. That is, the reinforcement material 50 includes the extension section 51 extending along the tapered surface of the second electrode 43.

When the vibration section 30A is displaced, the arm 30B is largely displaced, and thus a load is concentrated on the boundary between the first region A1 and the arm 30B (second region A2). In contrast, since the extension section 51 of the reinforcement material 50 having high fracture toughness is arranged across the boundary, it is possible to suppress damage to the vibration body 35 at the boundary between the first region A1 and the arm 30B (second region A2).

In the present embodiment, in the second region A2, a portion overlapping with the partition 22 surrounding the opening 21 of the substrate 20 is set as the base 30C, a portion from the base 30C to the first region A1 is set as the arm 30B, and the reinforcement material 50 is provided from the base 30C to the arm 30B.

When driving electric power is input to the piezoelectric element 40 to vibrate the vibration section 30A, the arm 30B is largely displaced, and the strain in the X direction also increases. The strain in the X direction spreads not only in the arm 30B but also from the arm 30B to the base 30C as shown in FIGS. 6 and 7. In the present embodiment, since the reinforcement material 50 is provided from the arm 30B to the base 30C, it is possible to resist the strain in the X direction as described above, and it is possible to further suppress damage to the vibration body 35.

The diaphragm 30 of the present embodiment is made of a plurality of materials different from each other, and the Young's modulus of the reinforcement material 50 is smaller than the Young's modulus of the material having the highest Young's modulus constituting the diaphragm 30. For example, when the diaphragm 30 is a layered body of SiO₂ and ZrO₂, the Young's modulus of SiO₂ is about 70 GPa, and the Young's modulus of ZrO₂ is about 200 GPa. In the second region A2, there is no ZrO₂ having a high Young's modulus, and the reinforcement material 50 is provided on SiO₂, and the Young's modulus of the reinforcement material 50 is smaller than that of the ZrO₂.

By this, it is possible to increase the displacement amount of the vibration section 30A compared to a case where the second region A2 is formed of SiO₂ and ZrO₂.

In the present embodiment, the reinforcement material 50 is made of any one of Au, Cu, and Al.

The reinforcement material 50 formed of these materials has higher fracture toughness than SiO₂ and ZrO₂ forming the first region A1, and has a smaller Young's modulus than ZrO₂. Therefore, the displacement amount at the time of displacement of the vibration section 30A can be increased by the reinforcement material 50 made of such a material, and even when the vibration section 30A is largely displaced, damage of the vibration body 35 can be suppressed by high fracture toughness.

### Second Embodiment

Next, a second embodiment will be described.

In the first embodiment, the diaphragm 30 is layered on the substrate 20 including the opening 21, and the region of the vibration section 30A in the vibration body 35 is defined by the partition 22 forming the opening 21, but the present embodiment is different from the first embodiment in that the vibration section 30A is defined by a suppression section provided on the opposite side of the substrate 20.

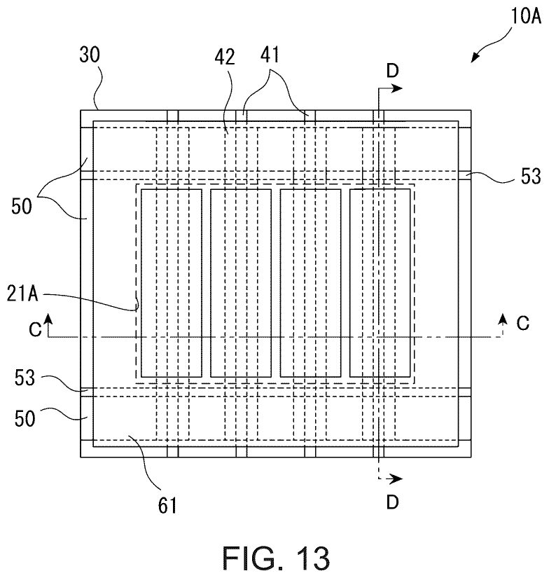

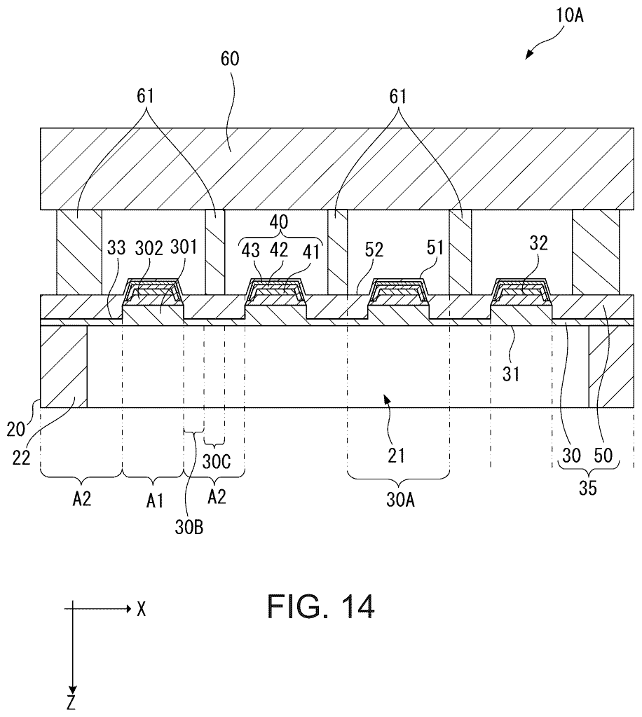

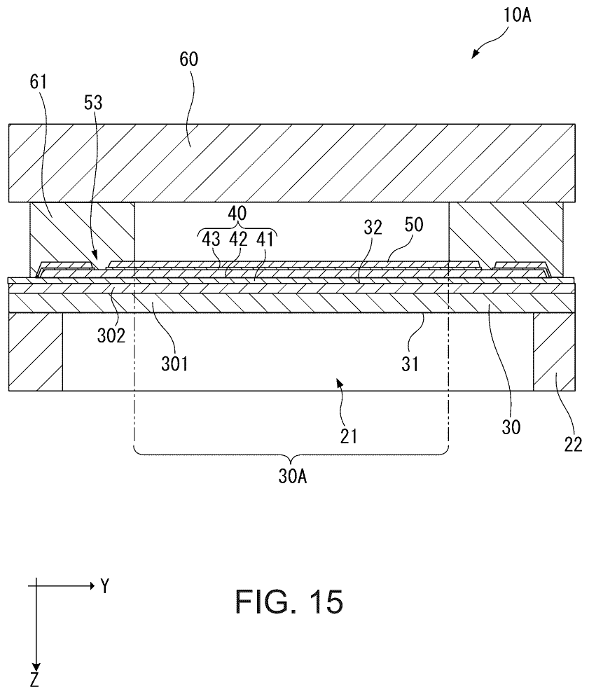

FIG. 13 is a plan view showing a schematic configuration of a piezoelectric device 10A of the second embodiment, FIG. 14 is a schematic cross-sectional view of the piezoelectric device 10A taken along line C-C of FIG. 13, and FIG. 15 is a schematic cross-sectional view of the piezoelectric device 10A taken along line D-D of FIG. 13.

In the following description, the same reference symbols are given to the components already described, and the description thereof is omitted or simplified.

In the present embodiment, as shown in FIGS. 13 to 15, the opening 21A of the substrate 20 is formed in a substantially rectangular shape, and a plurality of piezoelectric elements 40 which are long in the Y direction are arranged along the X direction in a region which overlaps with one opening 21A.

In the present embodiment, a wall section 61 as a suppression section is provided on a −Z side surface of the vibration body 35 so as to surround each piezoelectric element 40.

The wall section 61 has the same function as the partition 22 of the substrate 20 of the first embodiment. That is, in the vibration body 35 constituted by the diaphragm 30 and the reinforcement material 50, a portion overlapping the wall section 61 in the Z direction becomes the base 30C in which vibration is suppressed. A portion from the first region A1 to the base 30C is an arm 30B.

The configuration of the diaphragm 30, the piezoelectric element 40, and the reinforcement material 50 is the first embodiment.

Also in the present embodiment, the displacement characteristics as shown in FIGS. 6 to 10 described in the first embodiment can be obtained. That is, compared to the case where the driving voltage is 10 V, in the case where the driving voltage of 100 V is input to the piezoelectric device 10A, the vibration displacement amount of the vibration section 30A increases, but the strain in the X direction also increases by that amount. As shown in FIGS. 8 to 10, the strain in the X direction is shifted to a first surface 31 side as the driving voltage is increased, and thus the strain in the X direction on a second surface 32 side of the vibration body 35 is increased.

On the other hand, also in the present embodiment, the reinforcement material 50 similar to that of the first embodiment is provided. By this, it is possible to suppress the influence of the increase of the strain in the X direction. That is, even when a high driving voltage is input to the piezoelectric device 10A, it is possible to suppress damage to the vibration body 35, and it is also possible to increase the vibration displacement amount of the vibration section 30A as shown in FIGS. 11 and 12.

### Operations and Effects of the Present Embodiment

The piezoelectric device 10A of the present embodiment include the wall sections 61 (suppression section) that are provided on a second surface 32 side of the diaphragm 30 at positions sandwiching the piezoelectric elements 40 and that suppress vibration of the diaphragm 30 (vibration body 35).

In such a piezoelectric device 10A, as in the first embodiment, the region of each vibration section 30A of the vibration body 35 can be defined. Similarly to the first embodiment, by the reinforcement material 50, it is possible to suppress damage to the vibration body 35 and also it is possible to increase the displacement amount of the vibration section 30A.

In the present embodiment, a portion overlapping with the partition surrounding the opening of the substrate 20 is set as the base 30C, and the reinforcement material 50 is provided from the base 30C to the arm 30B.

In the present embodiment, since the reinforcement material 50 is provided from the arm 30B to the base 30C, similarly to the first embodiment, it is possible to resist the strain in the X direction and to suppress the damage of the vibration body 35.

### Third Embodiment

The piezoelectric devices 10 and 10A of the present disclosure can be used as various piezoelectric actuators in addition to the ultrasonic device as described in the first embodiment.

In a third embodiment, a liquid ejection device as a piezoelectric actuator using the piezoelectric device 10 will be exemplified.

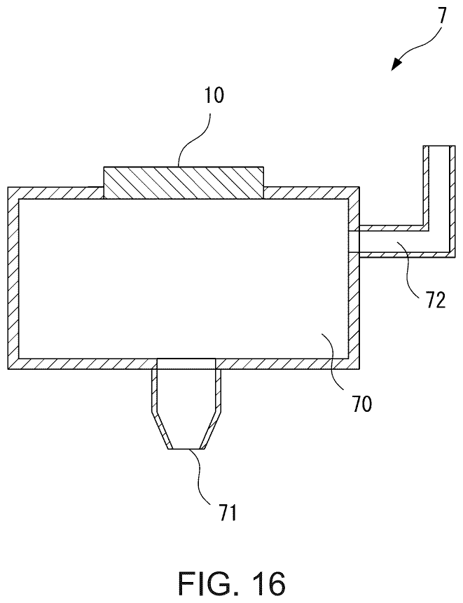

FIG. 16 is a diagram showing an example of a liquid ejection device.

In FIG. 16, a liquid ejection device 7 of the present embodiment includes a pressure chamber 70 in which the piezoelectric device 10 is arranged, a nozzle 71 arranged in a part of the pressure chamber 70, and an introduction section 72 for introducing liquid into the pressure chamber 70.

In the present embodiment, liquid such as ink is introduced into the pressure chamber 70 from the introduction section 72, and the pressure chamber 70 is filled with the liquid.

Then, when the driving voltage is inputted to the piezoelectric device 10, the vibration section 30A is displaced and driven, so that the pressure in the pressure chamber 70 increases and liquid is ejected from the nozzle 71. The piezoelectric device 10A described in the second embodiment may be used instead of the piezoelectric device 10.

In such a liquid ejection device 7, the pressure applied to the pressure chamber 70 may be increased according to, for example, the volume of the pressure chamber 70 or the distance from the liquid ejection device 7 to the ejection target. In this case, the pressure of the pressure chamber 70 can be increased by increasing the driving voltage input to the piezoelectric device 10, but as described above, the strain of the vibration body 35 in the X direction is increased by increasing the driving electric power.

In contrast, by using the piezoelectric device 10, it is possible to suppress damage of the vibration body 35 due to the reinforcement material 50. Further, with respect to the driving voltage to be input, it is possible to increase the displacement amount as compared with the piezoelectric device of the related art, it is possible to raise the pressure in the pressure chamber 70 with a smaller voltage.

### Modification

The present disclosure is not limited to the above-described embodiments, and configurations obtained by modifications, improvements, appropriate combinations of the embodiments, and the like within a range in which the object of the present disclosure can be achieved are included in the present disclosure.

### First Modification

In the second embodiment, a configuration in which the diaphragm 30 is arranged on the substrate 20 is exemplified, but a configuration in which the substrate 20 is not provided may be adopted. That is, in the second embodiment, even when the substrate 20 is not provided, the vibration section 30A can be partitioned by the wall section 61 which is the suppression section.

### Second Modification

In the above-described embodiment, the reinforcement material 50 is provided so that an upper surface (third surface 52) of the reinforcement material 50 and the second surface 32 of the diaphragm 30 are the same surface, but the present disclosure is not limited thereto. The reinforcement material 50 may be thin, and the third surface 52 may be located closer to the first surface 31 than the second surface 32. Alternatively, the reinforcement material 50 may be thick, and the third surface 52 may be located closer to the sealing plate 60 than the second surface 32.

### Overview of Present Disclosure

A piezoelectric device according to a first aspect of the present disclosure includes a substrate that includes an opening; a diaphragm that includes a first surface and a second surface opposite to the first surface, and that is configured such that the first surface is bonded to the substrate to close the opening; and a piezoelectric element provided on the second surface of the diaphragm, wherein the diaphragm includes a first region overlapping with the piezoelectric element and a second region not overlapping with the piezoelectric element when viewed from a thickness direction of the diaphragm, a thickness of the second region in the thickness direction of the diaphragm is thinner than a thickness of the first region, the second region is provided with a reinforcement material made of a material having a fracture toughness higher than that of the first region of the diaphragm, and the thickness of the second region in the thickness direction is constant, and a thickness of the reinforcement material is constant.

By this, even in a case where high driving electric power is input to the piezoelectric device, it is possible to suppress damage to the diaphragm and the reinforcement material, and to displace the diaphragm and the reinforcement material by a large displacement amount.

The piezoelectric device of the present aspect may be configured such that the diaphragm includes a recess that is recessed from a second surface side in the second region, a groove depth of the recess in the thickness direction is equal to or greater than a half value of the thickness of the first region, and the reinforcement material is arranged in the recess, and the thickness of the reinforcement material in the thickness direction is equal to or greater than the groove depth.

By this, when a high driving electric power is input to the piezoelectric device, the reinforcement material having a high fracture toughness is provided on a second surface side where the strain increases, and the damage of the diaphragm and the reinforcement material can be suppressed.

The piezoelectric device of the present aspect may be configured such that when viewed from the thickness direction, the reinforcement material extends to a position straddling a boundary between the first region and the second region.

By this, the boundary between the first region and the second region where the load tends to concentrate can be covered with the reinforcement material having a high fracture toughness, and the damage of the diaphragm and the reinforcement material at the boundary can be suppressed.

The piezoelectric device of the present aspect may be configured such that in the second region, a portion overlapping with a partition surrounding the opening of the substrate is set as a base, a portion from the base to the first region is set as an arm, and the reinforcement material is provided spanning from the base to the arm.

By this, even when high driving electric power is input to the piezoelectric device and the strain increases from the arm to the base, it is possible to suppress damage due to the strain by the reinforcement material.

The piezoelectric device of the present aspect may be configured such that the piezoelectric device includes a suppression section that is provided on a second surface side of the diaphragm at positions sandwiching the piezoelectric element and that is configured to suppress vibration of the diaphragm.

Even in the configuration in which the suppression section is provided on a second surface side of the diaphragm as in the present aspect, it is possible to define the vibration region in which the piezoelectric element of the diaphragm is arranged.

The piezoelectric device of the present aspect may be configured such that in the second region, a portion overlapping with the suppression section of the substrate is set as a base, a portion from the base to the first region is set as an arm, and the reinforcement material is provided spanning from the base to the arm.

By this, as in the above-described aspect, by inputting a high driving electric power to the piezoelectric device, even strain is increased over the arm to the base, it is possible to suppress damage due to the strain by the reinforcement material.

The piezoelectric device of the present aspect may be configured such that the diaphragm is made of a plurality of materials different from each other and a Young's modulus of the reinforcement material is smaller than a Young's modulus of a material having a highest Young's modulus constituting the diaphragm.

By this, as in the above-described aspect, the displacement amount of the diaphragm can be increased while suppressing damage of the diaphragm.

The piezoelectric device of the present aspect may be configured such that the reinforcement material is made of any one of Au, Cu, and Al.

By this, as in the above-described aspect, the displacement amount of the diaphragm can be increased while suppressing damage of the diaphragm. By constituting the reinforcement material by these materials having electrical conductivity, or to function the reinforcement material as a wiring electrode, it is possible to or to function as an electromagnetic shield.

The piezoelectric device of the present aspect may be configured such that the piezoelectric element is a layered body in which a first electrode, a piezoelectric film, and a second electrode are layered in order from the diaphragm.

By arranging such a piezoelectric element, the diaphragm can be driven to vibrate.

A piezoelectric actuator of a second aspect of the present disclosure includes the piezoelectric device according to the first aspect.

As described above, the piezoelectric device can suppress damage to the diaphragm even when the displacement amount of the diaphragm is large, and as a result, a piezoelectric actuator capable of outputting a large driving force can be provided.

An ultrasonic device of a third aspect of the present disclosure includes the piezoelectric device according to the first aspect.

As described above, the piezoelectric device can suppress damage to the diaphragm even when the displacement amount of the diaphragm is large, and as a result, an ultrasonic device capable of outputting a high sound pressure can be provided.

What is claimed is:

1. A piezoelectric device comprising:
a substrate that includes an opening;
a diaphragm that includes a first surface and a second surface opposite to the first surface, and that is configured such that the first surface is bonded to the substrate to close the opening; and
a piezoelectric element provided on the second surface of the diaphragm, wherein
the diaphragm includes a first region overlapping with the piezoelectric element and a second region not overlapping with the piezoelectric element when viewed from a thickness direction of the diaphragm,
a thickness of the second region in the thickness direction of the diaphragm is thinner than a thickness of the first region in the thickness direction of the diaphragm,
the second region is provided with reinforcement material having a fracture toughness higher than that of the first region of the diaphragm, and
the thickness of the second region in the thickness direction is constant, and a thickness of the reinforcement material is constant.

2. The piezoelectric device according to claim 1, wherein
the diaphragm includes a recess that is recessed from a second surface side in the second region,
a groove depth of the recess in the thickness direction is equal to or greater than a half value of the thickness of the first region, and
the reinforcement material is arranged in the recess, and the thickness of the reinforcement material in the thickness direction is equal to or greater than the groove depth.

3. The piezoelectric device according to claim 1, wherein
when viewed from the thickness direction, the reinforcement material extends to a position straddling a boundary between the first region and the second region.

4. The piezoelectric device according to claim 1, wherein
in the second region, a portion overlapping with a partition surrounding the opening of the substrate is set as a base, a portion from the base to the first region is set as an arm, and the reinforcement material is provided spanning from the base to the arm.

5. The piezoelectric device according to claim 1, further comprising:
a wall that is provided on a second surface side of the diaphragm at positions sandwiching the piezoelectric element and that is configured to suppress vibration of the diaphragm.

6. The piezoelectric device according to claim 5, wherein
in the second region, a portion overlapping with the wall of the substrate is set as a base, a portion from the base to the first region is set as an arm, and the reinforcement material is provided spanning from the base to the arm.

7. The piezoelectric device according to claim 1, wherein
the diaphragm is made of a plurality of materials different from each other and
a Young's modulus of the reinforcement material is smaller than a Young's modulus of a material having a highest Young's modulus constituting the diaphragm.

8. The piezoelectric device according to claim 1, wherein
the reinforcement material is made of any one of Au, Cu, and Al.

9. The piezoelectric device according to claim 1, wherein
the piezoelectric element is a layered body in which a first electrode, a piezoelectric film, and a second electrode are layered in order from the diaphragm.

10. A piezoelectric actuator comprising:
the piezoelectric device according to claim 1.

11. An ultrasonic device comprising:
the piezoelectric device according to claim 1.
